(19) United States
(12) Patent Application Publication
(10) Pub. No.: US 2020/0329551 A1
(43) Pub. Date: Oct. 15, 2020

(54) HEAT SINK FIXING MEMBER AND ELECTRONIC DEVICE

(71) Applicant: FUJITSU LIMITED, Kawasaki-shi (JP)

(72) Inventors: Tsuyoshi Yamamoto, Kawasaki (JP); Masumi SUZUKI, Kawasaki (JP); Tetsuro Yamada, Kawasaki (JP); Yasushi Masuda, Kawasaki (JP); JIE WEI, Hachioji (JP)

(73) Assignee: FUJITSU LIMITED, Kawasaki-shi (JP)

(21) Appl. No.: 16/836,984

(22) Filed: Apr. 1, 2020

(30) Foreign Application Priority Data
Apr. 10, 2019 (JP) 2019-074959

(51) Int. Cl. H05K 1/02; H05K 1/18; F28F 13/00

(52) U.S. Cl. CPC H05K 1/0203; H05K 1/181; F28F 13/00; H05K 2201/10674; F28F 2215/08; H05K 2201/10393; H05K 2201/10424; H05K 2201/10522; H05K 2201/10409

(57) ABSTRACT

A heat sink fixing member includes a frame that is provided above a board of a unit and surrounds a first electronic component and a first heat sink; and a blade in which both end parts are connected to the frame, a portion between the both end parts is erected in a gap in a first fin group, and a side closer to the board in the portion abuts on a first base plate, wherein the unit includes: the board; the first electronic component mounted on the board; and the first heat sink that is provided on the first electronic component, and has the first base plate and the first fin group that protrudes from the first base plate.

### CROSS-REFERENCE TO RELATED APPLICATION

This application is based upon and claims the benefit of priority of the prior Japanese Patent Application No. 2019-74959, filed on Apr. 10, 2019, the entire contents of which are incorporated herein by reference.

### FIELD

The embodiments discussed herein are related to a heat sink fixing member and an electronic device.

### BACKGROUND

There are known a technique of mounting a circuit element on an electronic circuit board, and a technique of mounting a member to cool a circuit element on the circuit element mounted on an electronic circuit board. Moreover, there is known a technique of placing a pressing jig having a spring property by a bent structure, on a member on a circuit element mounted on an electronic circuit board, and fixing the pressing jig with a fixing jig provided at both ends of the circuit element of the electronic circuit board. For example, Japanese Laid-open Patent Publication No. 2008-172110 and the like are disclosed as related art.

### SUMMARY

According to an aspect of the embodiments, a heat sink fixing member includes a frame that is provided above a board of a unit and surrounds a first electronic component and a first heat sink; and a blade in which both end parts are connected to the frame, a portion between the both end parts is erected in a gap in a first fin group, and a side closer to the board in the portion abuts on a first base plate, wherein the unit includes: the board; the first electronic component mounted on the board; and the first heat sink that is provided on the first electronic component, and has the first base plate and the first fin group that protrudes from the first base plate.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A to 1C are views (part 1) illustrating an example of an electronic device including a heat sink;

FIG. 2 is a view (part 2) illustrating an example of the electronic device including the heat sink;

FIGS. 3A and 3B are views (part 3) illustrating an example of the electronic device including the heat sink;

FIG. 4 is a view illustrating an example of a board unit according to a first embodiment;

FIG. 5 is a view illustrating an example of a heat sink fixing member according to the first embodiment;

FIG. 6 is a view illustrating an example of an electronic device according to the first embodiment;

FIG. 7 is a view illustrating a configuration example of the electronic device according to the first embodiment;

FIG. 8 is a view (part 1) illustrating a configuration example of the heat sink fixing member according to the first embodiment;

FIGS. 9A and 9B are views (part 2) illustrating a configuration example of the heat sink fixing member according to the first embodiment;

FIG. 10 is a view illustrating attachment of the heat sink fixing member to the board unit according to the first embodiment;

FIGS. 11A and 11B are views illustrating an example of pressing of a heat sink with the heat sink fixing member according to the first embodiment;

FIG. 12 is a view illustrating a modified example of the heat sink fixing member according to the first embodiment;

FIG. 13 is a view illustrating a first example of the electronic device according to the first embodiment;

FIGS. 14A and 14B are views illustrating a second example of the electronic device according to the first embodiment;

FIGS. 15A to 15C are views illustrating a third example of the electronic device according to the first embodiment;

FIGS. 16A and 16B are views illustrating a fourth example of the electronic device according to the first embodiment;

FIGS. 17A to 17C are views illustrating a fifth example of the electronic device according to the first embodiment;

FIG. 18 is a view illustrating a sixth example of the electronic device according to the first embodiment;

FIG. 19 is a view illustrating an example of an immersion cooling system according to a second embodiment; and

FIG. 20 is a view illustrating an example of electronic equipment according to a third embodiment.

### DESCRIPTION OF EMBODIMENTS

As one of methods of providing a heat sink for cooling an electronic component, on the heat-generating electronic component such as a large scale integration (LSI) mounted on a board, there is known a method of bonding the heat sink to the electronic component by using a thermal bonding material. In this method, as compared to such a method of providing a heat sink on an electronic component and fixing the heat sink to a board with a jig, it is possible achieve reduction of the number of jigs and a region for jigs to be secured on the board, improvement of a degree of freedom in wiring arrangement of the board and improvement of an electronic component mounting density due to the reduction, and the like. However, on the other hand, there is a case where it is difficult to stably fix the heat sink bonded on the electronic component and to stably maintain the fixed state. In view of the above, it is desirable to stably fix and hold the heat sink.

First, an example of an electronic device including a heat sink will be described.

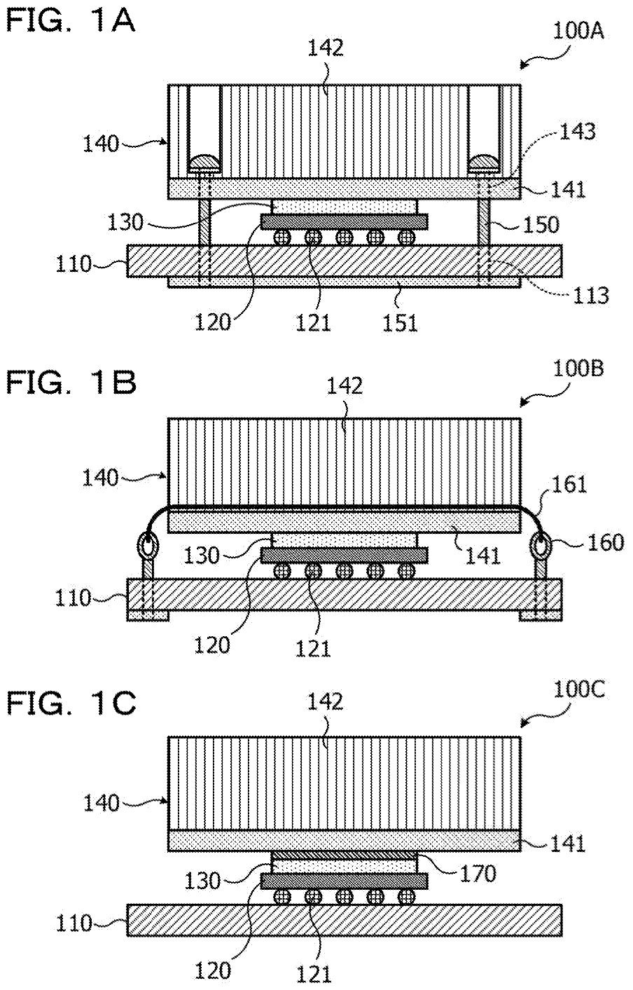

FIGS. 1A to 1C to 3A and 38 are views illustrating an example of an electronic device including a heat sink. FIGS. 1A to 1C, 2, 3A and 3B each are schematic cross-sectional views of a main part of an example of the electronic device.

An electronic device 100A illustrated in FIG. 1A includes a board 110, an electronic component 120, a heat spreader 130, and a heat sink 140.

As the board 110, a circuit board such as a printed board is used. As the electronic component 120, there is used a heat-generating electronic component that generates heat accompanying operation, for example, such as an LSI. The electronic component 120 is mounted on one surface (front surface) of the board 110 by flip-chip connection using a bump 121 provided on the electronic component 120. The heat spreader 130 is provided on the electronic component 120, and the heat sink 140 is provided on the heat spreader 130. For the heat sink 140 and the heat spreader 130, a material having a relatively high thermal conductivity such as aluminum or copper is used. Heat generated from the electronic component 120 accompanying operation of the electronic component 120 is transmitted, for example, from the heat spreader 130 to the heat sink 140, and is radiated from the heat sink 140 to the outside of the electronic device 100A. The heat sink 140 has a base plate 141 facing the heat spreader 130, and a group of fins 142 provided to protrude from the base plate 141. Providing the group of fins 142 increases a surface area of the heat sink 140, in other words, for example, a heat radiation area.

Note that, in the electronic device 100A, a thermally conductive material (such as a thermal interface material as described later) may be provided between the heat spreader 130 and the heat sink 140 in some cases.

In the electronic device 100A, a through hole 143 and a through hole 113 to be inserted with a screw 150 (or a screw or bolt with a spring) are individually provided on an outer side of a mounting region of the electronic component 120 in the heat sink 140 and the board 110. In the electronic device 100A, the screw 150 inserted into the through hole 143 and the through hole 113 is screwed to a reinforcing plate 151 provided on another surface (back surface) of the board 110. This causes the heat sink 140 to be fixed to the board 110, with the electronic component 120 and the like sandwiched in between.

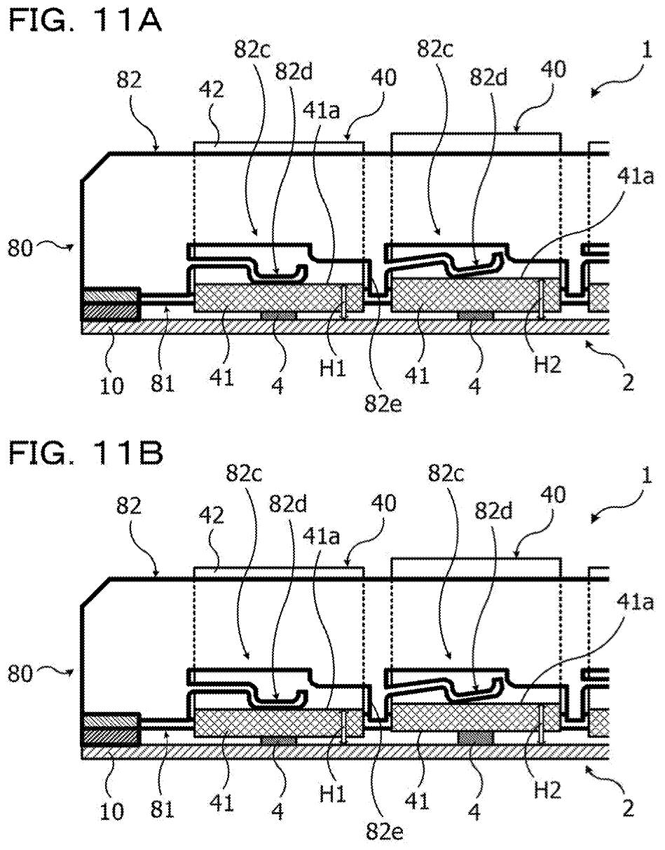

Furthermore, in an electronic device 1008 illustrated in FIG. 11, a hook 160 is attached to a board 110 on an outer side of a mounting region of an electronic component 120. Between the two hooks 160 is bridged with a wire 161 (or a retention wire or a spring) passing over a base plate 141 of a heat sink 140. In the electronic device 100B, the heat sink 140 is fixed to the board 110, with the electronic component 120 and the like sandwiched in between, by pressing the base plate 141 of the heat sink 140 with the wire 161 toward the board 110 side.

Note that, in the electronic device 100, a thermally conductive material (such as a TIM as described later) may be provided between a heat spreader 130 and the heat sink 140 in some cases.

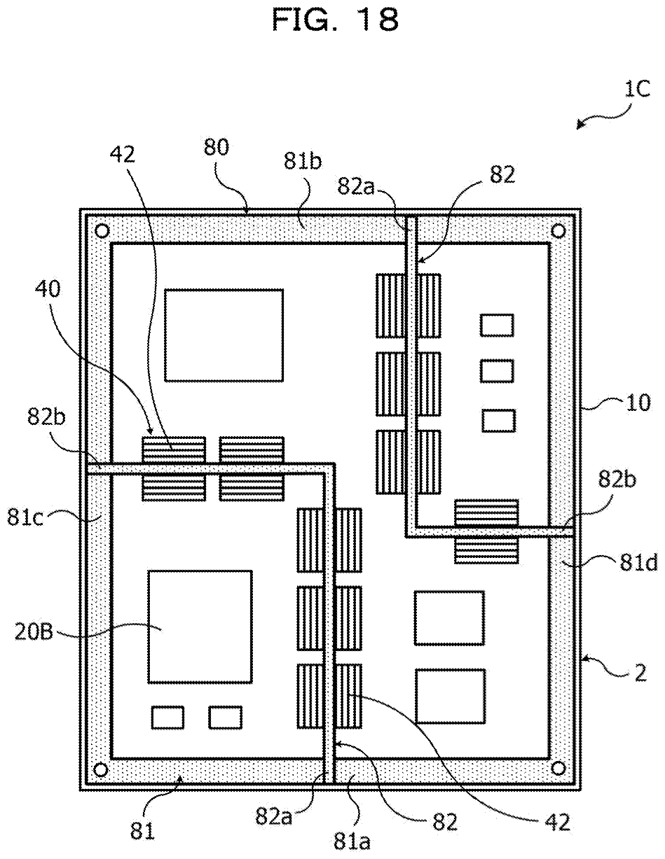

In the electronic device 100A (FIG. 1A) and the electronic device 100B (FIG. 18) having the configurations described above, as the heat sink 140, for example, one having a size or a surface area in accordance with a heating amount of the electronic component 120 is used. Therefore, the heat sink 140 provided on the electronic component 120 having a relatively large heating amount, such as an LSI, may be larger, or may be larger and have larger mass, than the electronic component 120. In the electronic device 100A and the electronic device 100B, even in a case where a relatively large and heavy heat sink 140 is thus provided, the screw 150, the reinforcing plate 151, the hook 160, and the wire 161 are used, and the heat sink 140 is relatively stably fixed to the board 110.

However, in the electronic device 100A and the electronic device 100B, in order to fix the heat sink 140, a region for passing the screw 150 or attaching the hook 160 is secured on an outer side of the mounting region of the electronic component 120 on the board 110. Since it is not possible to provide wiring or to mount other electronic components in such a region of the board 110, there is a possibility that a degree of freedom in wiring arrangement of the board 110 is deteriorated and an electronic component mounting density is deteriorated in the electronic device 100A and the electronic device 100B.

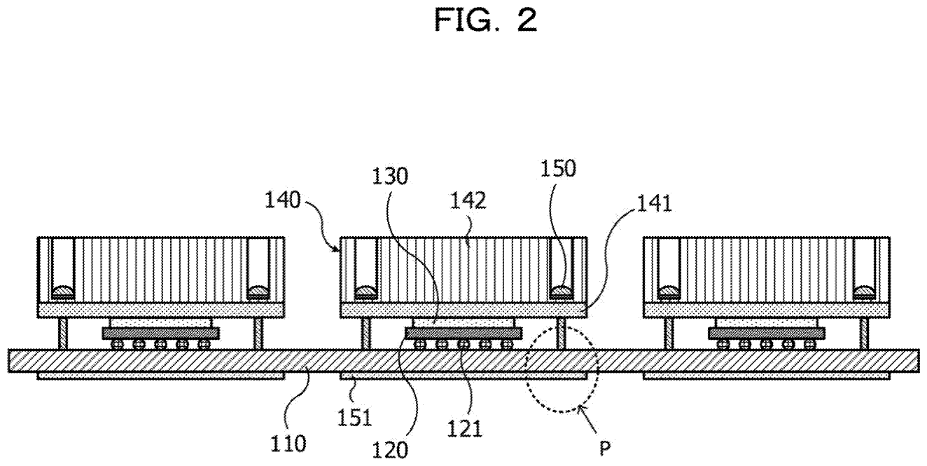

Here, FIG. 2 illustrates an example in which a group of the electronic components 120 is mounted on one board 110, and the heat sink 140 is fixed to the board 110 via the heat spreader 130 on each of the electronic components 120, by using the screw 150 and the reinforcing plate 151 as illustrated in FIG. 1A described above.

For example, in a region such as a portion P illustrated in FIG. 2, it is not possible to provide wiring or to mount other electronic components on the board 110, and there is a possibility that a degree of freedom in wiring arrangement may be deteriorated or an electronic component mounting density may be deteriorated in the board 110. In a case of adopting a structure in which the heat sink 140 is provided to each electronic component 120 via the heat spreader 130, the region such as the portion P illustrated in FIG. 2 is formed on an outer side of each electronic component 120. Therefore, a degree of freedom in wiring arrangement is deteriorated without being able to route the wiring between different electronic components 120, and an electronic component mounting density is deteriorated without being able to arrange different electronic components 120 close to each other. Increasing the number of electronic components 120 mounted on the board 110 may increase the influence of the deterioration of the degree of freedom in wiring arrangement and the electronic component mounting density due to the formation of the region such as the portion P may increase.

Note that, the same can be said for a case of adopting a configuration in which the heat sink 140 is fixed to the board 110, with use of the hook 160 and the wire 161 as illustrated in FIG. 18 described above, via the heat spreader 130 on each of a group of electronic components 120 mounted on one board 110.

Moreover, in the electronic device 100A, materials for the screw 150 and the reinforcing plate 151, and a process for fixing the heat sink 140 by using the screw 150 and the reinforcing plate 151 are needed for each electronic component 120. Furthermore, in the electronic device 100B, materials for the hook 160 and the wire 161, and a process for fixing the heat sink 140 by using the hook 160 and the wire 161 are needed for each electronic component 120. Therefore, in the electronic device 100A and the electronic device 1008, the cost for realizing the cooling of the electronic component 120 by using the heat sink 140 may be relatively high.

Whereas, as another method for fixing the heat sink 140 to cool the electronic component 120, there is a method as illustrated in FIG. 1C.

Similarly to the electronic device 100A (FIG. 1A) and the electronic device 1006 (FIG. 18), an electronic device 100C illustrated in FIG. 1C has a configuration in which an electronic component 120 is mounted on a board 110, and a heat spreader 130 is provided on the electronic component 120. In the electronic device 100C, a thermal interface material (TIM) 170 such as a thermally conductive adhesive, an adhesive sheet, or an adhesive film is provided on the heat spreader 130 on the electronic component 120, and a heat sink 140 is provided and bonded on the TIM 170.

In the electronic device 100C, deterioration of a degree of freedom in wiring arrangement and an electronic component mounting density of the board 110 as described above may be suppressed since the screw 150, the hook 160, and the like as described for the electronic device 100A and the electronic device 100 are not used. However, in the electronic device 100C, it may be difficult to stably hold the heat sink 140.

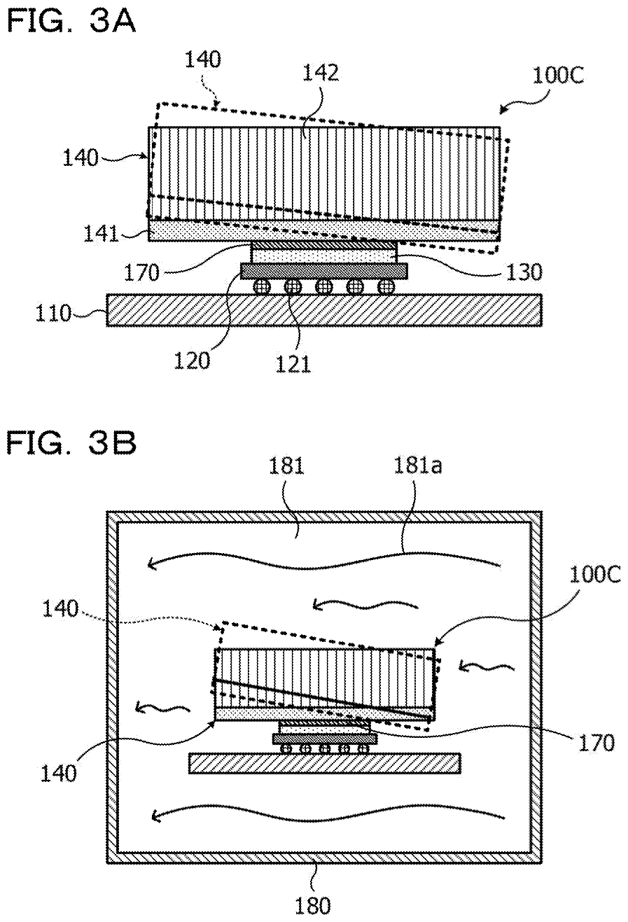

Here, a situation that may occur in the electronic device 100C will be described with reference to FIGS. 3A and 3B.

As described above, as the heat sink 140, one that is relatively large, or one that is large and heavy may be used in accordance with a heating amount of the electronic component 120. In a case where the heat sink 140 is to be bonded and fixed with the TIM 170 as in the electronic device 10C, an adhesive strength of the TIM 170 may be insufficient as the heat sink 140 becomes larger or heavier. If the adhesive strength of the TIM 170 is insufficient, the heat sink 140 is likely to come off from the TIM 170 and become unstable, as indicated by a dotted line in FIG. 3A.

For cooling of the electronic device 100C (the same applies to the electronic device 100A and the electronic device 100B), a liquid cooling system (immersion cooling system) in which the electronic device 100C is immersed in a cooling liquid 181 in an immersion tank 180 for cooling may be adopted as illustrated in FIG. 3B. In such a liquid cooling system, a flow 181a (not limited to one direction) of the cooling liquid 181 may occur in the immersion tank 180. In the electronic device 100C, resistance when such a flow 181a of the cooling liquid 181 collides may cause the heat sink 140 to come off from the TIM 170 and become unstable, as indicated by a dotted line in FIG. 30.

Note that, similarly, even in a case of adopting an air cooling method for cooling the electronic device 100C, the heat sink 140 may come off from the TIM 170 and become unstable due to resistance when a flow of cooling air collides.

Thus, in the electronic device 100C in which the heat sink 140 is bonded using the TIM 170, while it is possible to suppress deterioration of the degree of freedom in wiring arrangement and deterioration of the electronic component mounting density of the board 110, it may be difficult to stably fix and hold the heat sink 140.

In view of the above, here, the following configuration is adopted to realize stable fixing and holding of the heat sink.

### First Embodiment

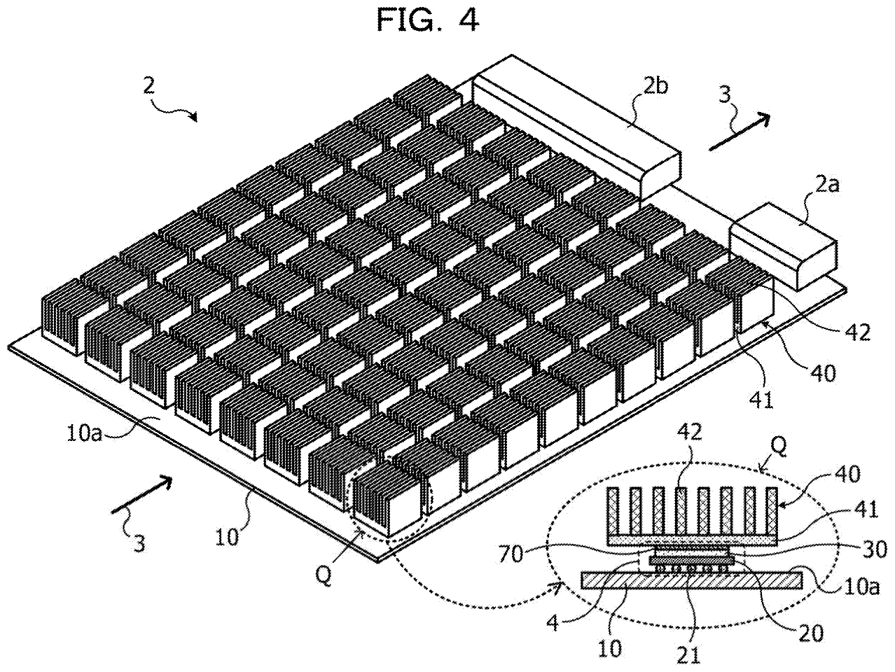

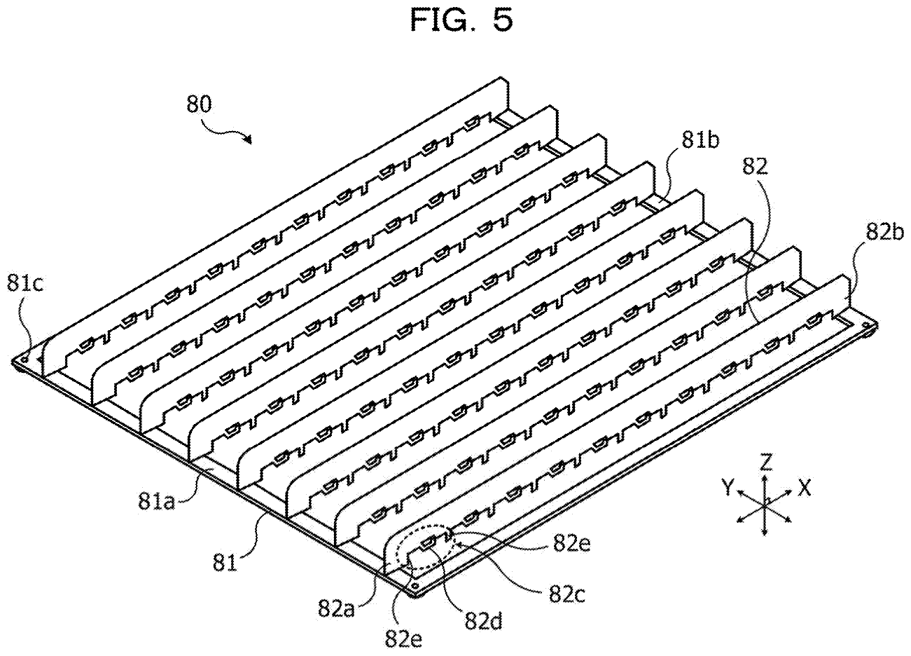

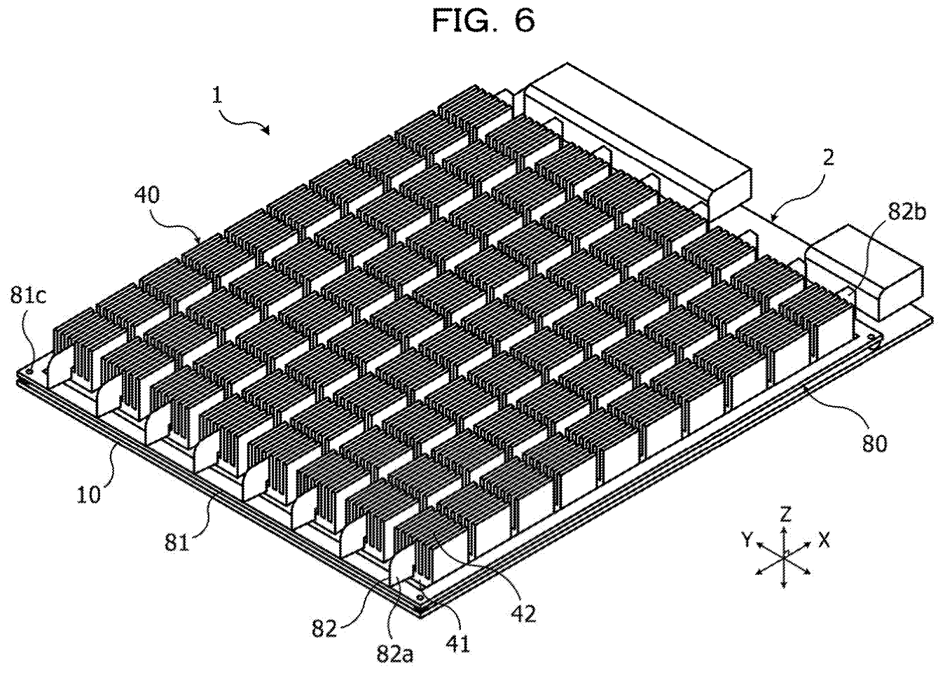

FIG. 4 is a view illustrating an example of a board unit according to a first embodiment, FIG. 5 is a view illustrating an example of a heat sink fixing member according to the first embodiment, and FIG. 6 is a view illustrating an example of an electronic device according to the first embodiment. FIGS. 4 to 6 are schematic external perspective views of an example of the board unit, an example of the heat sink fixing member, and an example of the electronic device, respectively. FIG. 4 includes a schematic cross-sectional view of a portion Q of the board unit together with an external perspective view.

First, an example of the board unit will be described with reference to FIG. 4.

A board unit 2 illustrated in FIG. 4 includes a board 10, and a group of heat sinks 40 (in this example, 80 pieces of 8 rows×10 rows) provided on one surface 10a side of the board 10. The board unit 2 may be provided on one surface 10a side of the board 10 with connectors 2a and 2b to be used for connection to another electronic device (such as a circuit board mounted with an electronic component).

In the board unit 2, an electronic component 20 is mounted in a region on the surface 10a of the board 10 where each heat sink 40 is provided, as illustrated in the cross section of the portion Q in FIG. 4. The heat sink 40 is provided to the electronic component 20 mounted on the board 10, via a heat spreader 30 and a TIM 70 on the heat spreader 30. The board unit 2 is provided with a structure such as the portion Q arranged longitudinally and laterally on the surface 10a of the board 10.

Note that the heat spreader 30 is not necessarily provided on the electronic component 20. In this case, the TIM 70 is provided on the electronic component 20 without via the heat spreader 30.

Here, as the board 10, various circuit boards such as a printed board are used. As the electronic component 20, an electronic component such as an LSI that generates heat accompanying operation is used. The electronic component 20 is mounted on the surface 10a of the board 10 by flip-chip connection using a bump 21 provided on the electronic component 20, and is electrically connected to the board 10. The heat spreader 30 is provided on the electronic component 20 mounted on the board 10, and the TIM 70 such as a thermally conductive adhesive, an adhesive sheet, or an adhesive film is provided on the heat spreader 30. The heat sink 40 is provided and bonded onto the TIM 70. The electronic component 20 is thermally connected to the heat sink 40 via the heat spreader 30 and the TIM 70.

For the heat sink 40 and the heat spreader 30, a material having a relatively high thermal conductivity such as aluminum or copper is used. Heat generated accompanying operation of the electronic component 20 is, for example, transmitted from the electronic component 20 to the heat spreader 30, transmitted from the heat spreader 30 to the heat sink 40 via the TIM 70, and radiated from the heat sink 40 to the outside of the board unit 2. This causes the electronic component 20 to be cooled, and suppresses overheating thereof.

Note that a heat radiation path of the heat generated from the electronic component 20 is not limited to such a path. For example, there are a path for directly radiating from the electronic component 20 to the outside, a path for transmitting from the electronic component 20 to the board 10 and radiating from the board 10 to the outside, and the like.

The heat sink 40 has a base plate 41 facing the TIM 70 side and bonded to the TIM 70, and a group of fins 42 provided to protrude upward (a side opposite to the TIM 70 side) from the base plate 41. For example, the group of flat fins 42 is provided on the base plate 41 in parallel, with planes facing each other. In this case, the heat sink 40 is preferably provided in a direction in which the group of flat fins 42 are to be parallel to a refrigerant flow 3, which is, for example, a flow of a cooling liquid during liquid cooling (immersion cooling) or a flow of cooling air during air cooling. Providing the group of fins 42 increases a surface area of the heat sink 40, in other words, for example, a heat radiation area.

The base plate 41 and the group of fins 42 of the heat sink 40 may be a part functioning as the base plate 41 and a part functioning as the group of fins 42 in one member, or may be obtained by attaching a member functioning as the group of fins 42 to a member functioning as the base plate 41.

In the following description, a structure provided between the board 10 and the heat sink 40 is also referred to as “component unit”. For example, among: the electronic component 20 mounted on the board 10; the heat spreader 30 provided thereon; and the TIM 70 provided further thereon, a structure including at least the electronic component 20 (including the bump 21) and the TIM 70 is referred to as “component unit”. In the example of FIG. 4, the electronic component 20, the heat spreader 30, and the TIM 70 provided between the board 10 and the heat sink 40 are referred to as “component unit 4”.

Subsequently, an example of a heat sink fixing member will be described with reference to FIG. 5.

A heat sink fixing member 80 illustrated in FIG. 5 is mounted on the board unit 2 as described above. The heat sink fixing member 80 includes a frame 81 and a group of blades (or plates) 82 connected to the frame 81.

The frame 81 has a shape so as to surround, for example, the group of heat sinks 40 and a group of component units 4 individually provided under the group of heat sinks 40, in the board unit 2 as described above. For example, the frame 81 has a rectangular shape extending along an outer peripheral portion on the board 10, in conformity with an outer shape of the board 10 provided with the group of heat sinks 40 and the group of component units 4. The frame 81 is provided with a mechanism to fix the frame 81 to the board 10, for example, a screw hole 81c to be used when the frame 81 is screwed to the board 10.

The group of blades 82 individually bridges between opposed portions 81a and 81b of the frame 81, and both end parts 82a and 82b are connected to the portions 81a and 81b of the frame 81, respectively. Each blade 82 has a plate shape, and both end parts 82a and 82b are connected to the frame 81 so that the blade 82 erects in a normal direction (a Z direction) of a surface (an XY plane) surrounded by the frame 81 (so that the plane of the blade 82 is parallel to the Z direction). Each of the group of blades 82 is provided corresponding to one row of the group of heat sinks 40 (in this example, ten pieces of one row arranged in the X direction) in the board unit 2. Each blade 82 is provided with a pressing part 82d that presses the heat sink 40 and a guide part 82e that guides the heat sink 40, at a portion 82c corresponding to each heat sink 40 in the corresponding row. Note that details of the pressing part 82d and the guide part 82e of the blade 82 will be described later.

For each of the frame 81 and the blade 82, various conductive and insulating materials can be used. For example, as described later, when the blade 82 is used as a part of the heat radiation member together with the heat sink 40, a conductive material having a relatively high thermal conductivity, for example, a conductive material such as stainless steel, aluminum, or copper is used for the blade 82. Furthermore, as described later, for avoiding an electrical short circuit via the blade 82 between the heat sinks 40 provided at different positions in contact with one blade 82, an insulating material is used for the blade 82. For avoiding an electrical short circuit via the blade 82, a surface of the blade 82 using a conductive material may be coated with an insulating material. Similarly, a conductor material may be used or an insulating material may be used for the frame 81, or an insulating material may be coated on the surface of the frame 81 using a conductive material. A same kind of material may be used for the blade 82 and the frame 81, or different kinds of materials may be used.

Next, an example of an electronic device in which the heat sink fixing member 80 is attached to the board unit 2 will be described with reference to FIG. 6.

An electronic device 1 illustrated in FIG. 6 includes the board unit 2 as illustrated in FIG. 4 described above, and the heat sink fixing member 80 as illustrated in FIG. 5 described above. The heat sink fixing member 80 is arranged on the board 10 so that the frame 81 of the heat sink fixing member 80 surrounds a region provided with the group of heat sinks 40 in the board unit 2, and the group of component units 4 (for example, FIG. 4) under the group of heat sinks 40. The frame 81 is fixed to the board 10 by, for example, a screwing method using the screw hole 81c.

At this time, each of the group of blades 82 of the heat sink fixing member 80 whose both end parts 82a and 82b are connected to the frame 81 is individually inserted into a gap between adjacent fins 42 of each of the group of heat sinks 40 in the corresponding row. In the group of blades 82 inserted into the gap between the adjacent fins 42 of each heat sink 40, a side closer to the group of component units 4 and the board 10 abuts on the base plate 41 (an upper surface thereof) in the gap between the fins 42. Note that details of the abutting between the blade 82 and the base plate 41 will be described later.

In the electronic device 1, by attaching, to a predetermined position of the board unit 2, the heat sink fixing member 80 in which the group of blades 82 is connected at a predetermined position of the frame 81 having a predetermined size, the group of heat sinks 40 in each row is collectively fixed by each blade 82.

Description will be further made on a configuration example of the electronic device 1 (FIG. 6) in which the heat sink fixing member 80 (FIG. 5) is attached to the board unit 2 (FIG. 4) and on a configuration example of the heat sink fixing member 80.

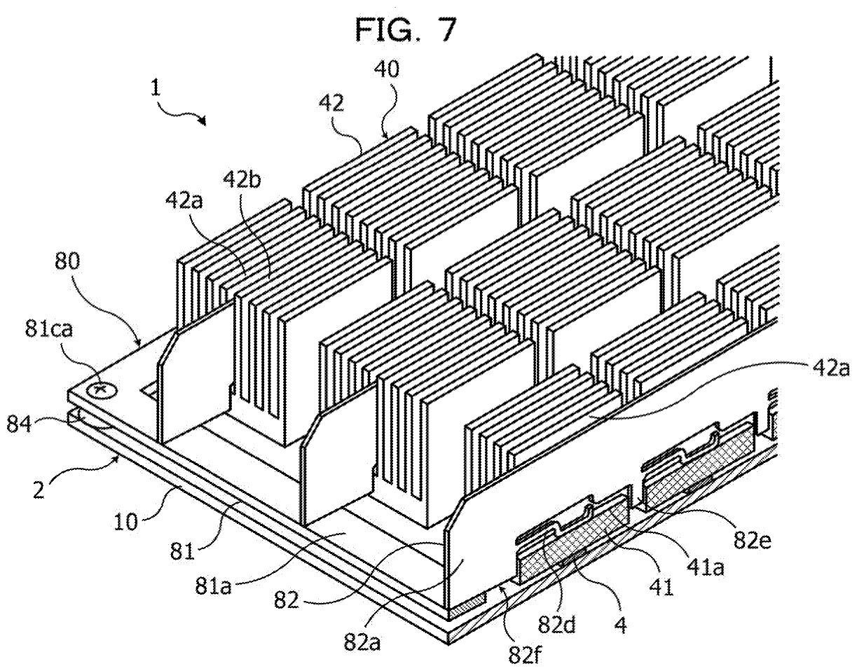

FIG. 7 is a view illustrating a configuration example of the electronic device according to the first embodiment. FIG. 7 is a schematic perspective view of a main part of an example of the electronic device. Here, FIG. 7 is a schematic perspective view of a main part including a cross section along a plane of the blade of the heat sink fixing member of an example of the electronic device.

As illustrated in FIG. 7, the electronic device 1 includes the board unit 2 and the heat sink fixing member 80 attached to the board unit 2.

The board unit 2 has a configuration in which the heat sink 40 is provided on each of a group of component units 4 (each including, for example, the electronic component 20, the heat spreader 30, and the TIM 70 as illustrated in FIG. 4) mounted on the board 10. The group of component units 4 and the group of heat sinks 40 are aligned and provided on the board 10.

The heat sink fixing member 80 includes: the frame 81 surrounding the group of component units 4 and the group of heat sinks 40 above the board 10; and a group of blades 82 whose end parts 82a are connected to the frame 81. Each of the group of blades 82 is provided at a position corresponding to one row the group of heat sinks 40 in the board unit 2.

The frame 81 of the heat sink fixing member 80 is fixed to the board 10 of the board unit 2 with a screw 81ca. At this time, each of the group of blades 82 of the heat sink fixing member 80 is inserted into a gap between adjacent fins 42 (fins 42a, 42b) of each of the group of heat sinks 40 in each row on the board unit 2. In each blade 82 inserted into the gap between the adjacent fins 42, a predetermined portion of a side (an edge part 82f) closer to the board 10 abuts on the upper surface 41a of the base plate 41 in the gap between the adjacent fins 42. The side closer to the board 10 in each blade 82 includes the pressing part 82d that presses the base plate 41 of the heat sink 40 toward the component unit 4 and the board 10, and the guide part 82e that guides a side surface of the heat sink 40.

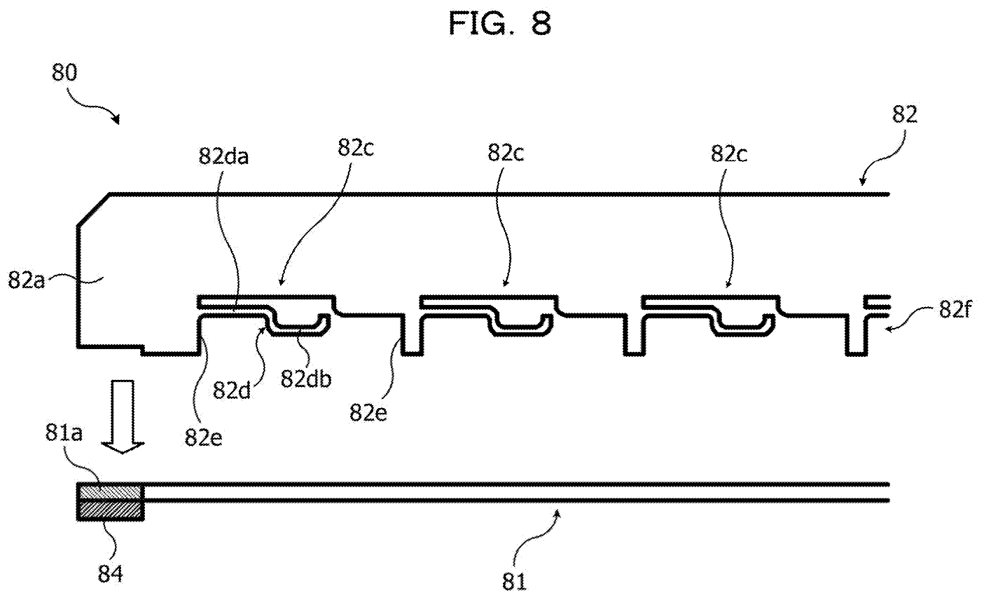

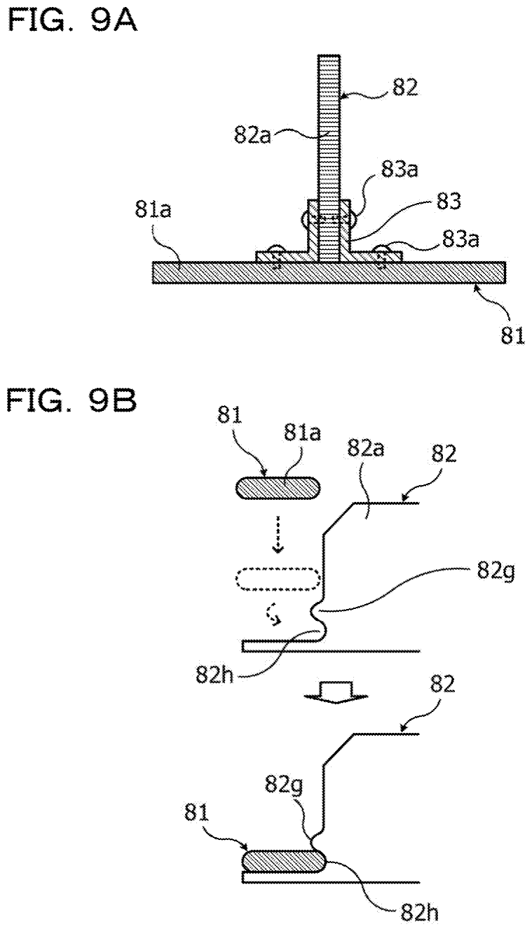

FIGS. 8 and 9A and 98 are views illustrating a configuration example of the heat sink fixing member according to the first embodiment. FIGS. 8 and 9A and 98 are schematic cross-sectional views of a main part of an example of the frame and the blade of the heat sink fixing member. Here, FIG. 8 is a schematic exploded cross-sectional view when the heat sink fixing member is cut in a direction along a plane of one blade. FIG. 9A is a schematic cross-sectional view of a connection part between the frame and the blade when the heat sink fixing member is cut in a direction orthogonal to a direction along a plane of one blade. FIG. 98 is a schematic cross-sectional view of the connection part between the frame and the blade when the heat sink fixing member is cut in a direction along a plane of one blade.

The heat sink fixing member 80 includes, for example, the blade 82 having a shape as illustrated in FIG. 8. In the blade 82, the pressing part 82d and the guide part 82e are provided in the portion 82c corresponding to each heat sink 40 in the board unit 2.

When the blade 82 is inserted into a gap between adjacent fins 42 of the heat sink 40, the pressing part 82d abuts on the base plate 41 (the upper surface 41a thereof) in the gap between the adjacent fins 42. The pressing part 82d has a so-called cantilever beam (or cantilever spring) shape in which one end side is fixed to a main body of the blade 82 and another end side is a free end. This shape realizes the pressing part 82d having a spring property in which the free end side is vertically displaced while the one end side is supported by the main body of the blade 82. Exemplified here is the pressing part 82d having a support part 82da extending laterally from the main body of the blade 82, and an abutting part 82db extending one step downward and laterally from the support part 82da. When the heat sink fixing member 80 is attached to the board unit 2, such an abutting part 82db of the pressing part 82d abuts on the base plate 41 of the heat sink 40.

The guide part 82e is provided at a position so as to face a side surface of the heat sink 40 with the heat sink 40 interposed in between when the blade 82 is inserted into a gap between adjacent fins 42 of the heat sink 40, and the pressing part 82d abuts on the base plate 41 in the gap. The guide part 82e may be positioned with a fixed clearance provided between with the side surface of the heat sink 40, or may be positioned without a fixed clearance provided (in other words, for example, in contact with the side surface of the heat sink 40). By providing the guide part 82e to the blade 82, the heat sink fixing member 80 is attached to the board unit 2 in a state where the side surface of the heat sink 40 is guided by the guide part 82e and each heat sink 40 is accommodated in each portion 82c.

The pressing part 82d and the guide part 82e are formed, for example, by performing cutout processing on a plate material to be the blade 82, into a predetermined shape by using a processing technique such as laser cutting or press cutting.

The one end part 82a of the blade 82 provided with the pressing part 82d and the guide part 82e as described above is connected to one portion 81a among opposing portions of the frame 81 as illustrated in FIG. 8. Note that the frame 81 may be provided with a spacer 84 interposed between with the board 10 of the board unit 2 when the heat sink fixing member 80 is attached to the board unit 2.

The end part 82a of the blade 82 and the portion 81a of the frame 81 may be connected using, for example, a welding technique. This causes the heat sink fixing member 80 to be formed in which the blade 82 and the frame 81 are integrated. Note that a method of connecting the end part 82a of the blade 82 and the portion 81a of the frame 81 is not limited to welding.

For example, as illustrated in FIG. 9A, the end part 82a of the blade 82 is erected on the portion 81a of the frame 81, an L-shaped member 83 (metal fitting and the like) is applied to a base of the portion 81a, and the member 83 is fixed to the blade 82 and the frame 81 individually with a screw 83a. Such a method may be used to connect the end part 82a of the blade 82 to the portion 81a of the frame 81.

Furthermore, as illustrated in FIG. 98, as the blade 82, there may be used a blade provided with a locking part 82g at a side end part of the blade and a fitting part 82h located below the locking part 82g. The frame 81 is moved along the side end part of such a blade 82 (an upper figure in FIG. 98), moved over the locking part 82g (an upper figure in FIG. 9B), and fitted to the fitting part 82h (a lower figure in FIG. 98). When the frame 81 fitted to the fitting part 82h is locked by the locking part 82g, the frame 81 and the blade 82 are fixed. Such a method may be used to connect the end part 82a of the blade 82 to the portion 81a of the frame 81.

Here, while the connection between one end part 82a of the blade 82 and one portion 81a of the frame 81 has been illustrated, the connection between another end part 82b of the blade 82 and another portion 81b of the frame 81 is similarly performed in accordance with the example of FIG. 8 and FIG. 9A or FIG. 98.

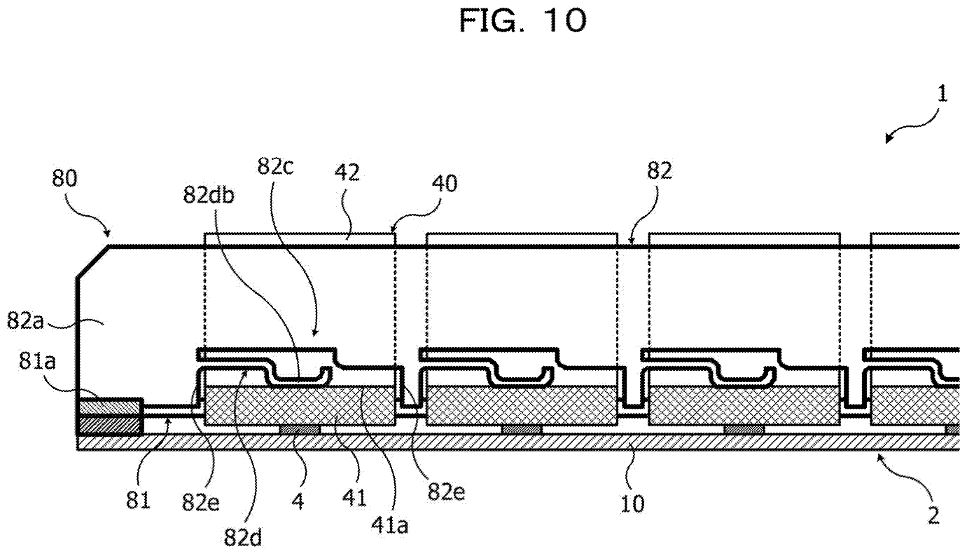

FIG. 10 is a view illustrating attachment of the heat sink fixing member to the board unit according to the first embodiment. FIG. 10 is a schematic cross-sectional view of a main part of an example of the electronic device in which the heat sink fixing member is attached to the board unit. Here, FIG. 10 is a schematic cross-sectional view of the electronic device when the heat sink fixing member is cut in a direction along a plane of one blade.

In the electronic device 1, the heat sink fixing member 80 in which the blade 82 is connected and integrated with the frame 81 is attached to the board unit 2 including a group of heat sinks 40 individually provided on a group of component units 4 (each including, for example, the electronic component 20, the heat spreader 30, and the TIM 70 as illustrated in FIG. 4) arranged on the board 10 as illustrated in FIG. 10. In one row of the group of heat sinks 40 corresponding to one blade 82, each side surface is guided by the guide part 82e, the blade 82 is inserted into a gap between individual adjacent fins 42, and the pressing part 82d (the abutting part 82db thereof) of the blade 82 abuts on the upper surface 41a of the base plate 41 in the gap.

Note that, in the electronic device 1, the component unit 4 is generally provided so as to be located at a center of the heat sink 40 in plane view and cross-sectional view. Therefore, a configuration of the heat sink fixing member 80 is adjusted in advance so that, for example, the blade 82 is inserted into a gap between adjacent fins 42 located at the center of the heat sink 40, and the pressing part 82d (the abutting part 82db thereof) abuts on the center of the heat sink 40.

The pressing part 82d of the blade 82, which abuts on the upper surface 41a of the base plate 41 of the heat sink 40, presses, with the spring property thereof, the base plate 41 toward the component unit 4 and toward the board 10 mounted with the component unit 4. By pressing the base plate 41 with the pressing part 82d having the spring property in this way, the heat sink 40 is stably fixed, and the fixed state is stably maintained. The heat sink fixing member 80 allows the group of heat sinks 40 in each row corresponding to each blade 82 to be collectively and stably fixed and held.

By pressing and fixing the heat sink 40 (the base plate 41 thereof) with the blade 82 (the pressing part 82d thereof), appropriate pressure is applied to the TIM 70 (FIG. 4) of the component unit 4. Therefore, the adhesion between the component unit 4 and the heat sink 40 is increased, or deterioration of the adhesion is suppressed. As a result, a thermal resistance between the component unit 4 and the heat sink 40 is reduced, or an increase in the thermal resistance is suppressed, realizing efficient heat transmission from the component unit 4 to the heat sink 40. This may effectively suppress overheating of the electronic component 20 (FIG. 4) of the component unit 4, and suppress damage and performance deterioration of the electronic component 20 due to the overheating.

Since the heat sink 40 is stably fixed and held by the heat sink fixing member 80, a material having a lower adhesive strength can be used for the TIM 70 (FIG. 4) of the component unit 4 than that in a case where the heat sink 40 is to be fixed and held by the adhesive strength of the TIM 70 (FIG. 1C). By using a material having a relatively high thermal conductivity for the TIM 70 of the component unit 4, in spite of a relatively low adhesive strength, efficient heat transmission from the component unit 4 to the heat sink 40 is realized. The use of the heat sink fixing member 80 enables selection of a material for the TIM 70 attaching importance to thermal conductivity rather than the adhesive strength.

When a conductive material is used for the blade 82 of the heat sink fixing member 80, for example, the blade 82 is thermally connected to the heat sink 40 by abutting on the base plate 41, and functions as a part of a heat radiation member together with the heat sink 40. This increases the heat radiation area in the electronic device 1, and enhances the heat radiation efficiency.

The blade 82 of the heat sink fixing member 80, which is inserted into a gap between adjacent fins 42 of the heat sink 40, also functions, together with the group of fins 42, as a straightening plate for a refrigerant such as a cooling liquid during liquid cooling or a cooling air during air cooling. This suppresses turbulence of the refrigerant in each heat sink 40, then suppresses the turbulence to send the refrigerant to the downstream side, suppresses stagnation of a heated refrigerant, and enhances the radiation efficiency.

Furthermore, the heat sink fixing member 80 may cope with a height difference of the group of heat sinks 40 and a height difference of the group of component units 4, by providing the pressing part 82d of the blade 82 with a spring property. This point will be described with reference to the following FIGS. 11A and 118.

FIGS. 11A and 11B are views illustrating an example of pressing of the heat sink with the heat sink fixing member according to the first embodiment. FIGS. 11A and 11B each are schematic cross-sectional views of a main part of an example of the electronic device. Here, FIGS. 11A and 118 each are schematic cross-sectional views of the electronic device when the heat sink fixing member is cut in a direction along a plane of one blade.

FIG. 11A exemplifies a case where the heat sinks 40 having different thicknesses of the base plate 41 are included in the group of heat sinks 40 fixed by one blade 82. Note that, in the example of FIG. 11A, heights of the group of component units 4 (each including, for example, the electronic component 20, the heat spreader 30, and the TIM 70 as illustrated in FIG. 4) are the same. At a certain portion 82c of the blade 82, there is provided a heat sink 40 having a height H1 from the board 10 to the upper surface 41a of the base plate 41. At another portion 82c of the blade 82, there is provided a heat sink 40 having a height H2, which is higher than H1, from the board 10 to the upper surface 41a of the base plate 41.

Even in the case illustrated in FIG. 11A, in the heat sink fixing member 80, the pressing part 82d of the blade 82 is displaced by the spring property in accordance with a height of the upper surface 41a of the base plate 41 of the heat sink 40. In other words, for example, the pressing part 82d that presses the heat sink 40 whose upper surface 41a of the base plate 41 is located at the height H2 (>H1) is further displaced as compared with the pressing part 82d that presses the heat sink 40 whose upper surface 41a of the base plate 41 is located at the height H1. In the heat sink fixing member 80, the pressing part 82d having the spring property may press, toward the component unit 4 and the board 10, the group of heat sinks 40 whose upper surfaces 41a of the base plates 41 are located at different heights, while absorbing the difference (or variation) in height thereof, and may stably fix and hold the group of heat sinks 40.

Furthermore, FIG. 11B exemplifies a case where the group of component units 4 (each including, for example, the electronic component 20, the heat spreader 30, and the TIM 70 as illustrated in FIG. 4) provided under the group of heat sinks 40 fixed by one blade 82 includes component units 4 having different heights. Examples of the component units 4 having different heights include, for example, the component units 4 having different heights of the electronic components 20, having different thicknesses of the heat spreaders 30, having different thicknesses of the TIMs 70, having different mounting heights of the electronic component 20 (height of the bump 21), and the like. Note that, in the example of FIG. 11B, the thickness of the base plates 41 of the group of heat sinks 40 is the same. At a certain portion 82c of the blade 82, the height of the component unit 4 is relatively low, and the height from the board 10 to the upper surface 41a of the base plate 41 of the heat sink 40 is H1. At another portion 82c of the blade 82, the height of the component unit 4 is relatively high, and the height from the board 10 to the upper surface 41a of the base plate 41 of the heat sink 40 is H2 higher than H1.

Even in the case illustrated in FIG. 11B, in the heat sink fixing member 80, the pressing part 82d of the blade 82 is displaced by the spring property in accordance with a height of the upper surface 41a of the base plate 41 of the heat sink 40. In other words, for example, the pressing part 82d that presses the heat sink 40 whose upper surface 41a of the base plate 41 is located at the height H2 (>H1) is further displaced as compared with the pressing part 82d that presses the heat sink 40 whose upper surface 41a of the base plate 41 is located at the height H1. In the heat sink fixing member 80, the pressing part 82d having the spring property may press, toward the component unit 4 and the board 10, the group of heat sinks 40 whose upper surfaces 41a of the base plates 41 are located at different heights, while absorbing the difference (or variation) in height thereof, and may stably fix and hold the group of heat sinks 40.

The heat sink fixing member 80 may realize the electronic device 1 in which the group of heat sinks 40 above the board 10 are stably fixed and held even if the group of heat sinks 40 has different heights up to the upper surface 41a of the base plate 41.

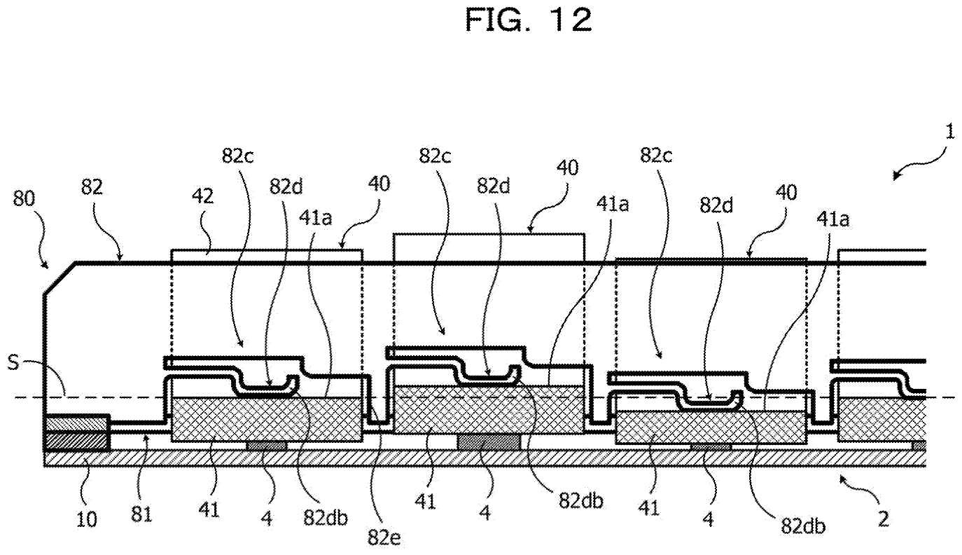

Furthermore, as illustrated in the following FIG. 12, the configuration of the heat sink fixing member 80 may be changed on the basis of the height difference in the group of heat sinks 40 and the height difference in the group of component units 4 existing in the board unit 2.

FIG. 12 is a view illustrating a modified example of the heat sink fixing member according to the first embodiment. FIG. 12 is a schematic cross-sectional view of a main part of an example of the electronic device. Here, FIG. 12 is a schematic cross-sectional view of the electronic device when the heat sink fixing member is cut in a direction along a plane of one blade.

In the electronic device 1, for example, as illustrated in FIG. 12, the board unit 2 may be mounted with, on the board 10 thereof, component units 4 (including, for example, the electronic component 20, the heat spreader 30, and the TIM 70 illustrated in FIG. 4) and the heat sink 40 having different sizes, in some cases. On the basis of a height of the upper surface 41a of the base plate 41 from the board 10 that is determined when the component units 4 and the heat sink 40 having different sizes are mounted above the board 10 in this way, a height of the pressing part 82d of the blade 82 may be adjusted in advance.

In other words, for example, in the example of FIG. 12, in the heat sink 40 (on the leftmost side) provided via the component unit 4 on the board 10 corresponding to a certain portion 82c of the blade 82, the height of the upper surface 41a of the base plate 41 from the board 10 is set as a reference S. Then, on the board 10, the portion 82c of the blade 82 corresponding to a region provided with the component unit 4 and the heat sink 40 (second from the left) having a relatively large size, the pressing part 82d is provided such that the abutting part 82db is at a position higher than the reference S. Furthermore, on the board 10, the portion 82c of the blade 82 corresponding to a region provided with the component unit 4 and the heat sink 40 (third from the left) having a relatively small size, the pressing part 82d is provided such that the abutting part 82db is at a position lower than the reference S.

As described above, in the blade 82 of the heat sink fixing member 80, the height of the pressing part 82d may be adjusted on the basis of the size of the component unit 4 and the heat sink 40 provided corresponding to each portion 82c.

As in the example of FIG. 12, the blade 82 of the heat sink fixing member 80 does not need to be provided with only the pressing parts 82d having a same height, but may be provided with the pressing parts 82d having different heights. As for the board unit 2 to be attached with the heat sink fixing member 80, the board unit 2 does not need to be provided with only the component units 4 having a same height, but may be provided with component units 4 having different heights.

On the basis of the size of the component unit 4 and the heat sink 40 provided corresponding to each portion 82c, the heat sink fixing member 80 in which the height of the pressing part 82d is adjusted is used, and the electronic device 1 is realized in which the group of heat sinks 40 above the board 10 is stably fixed and held.

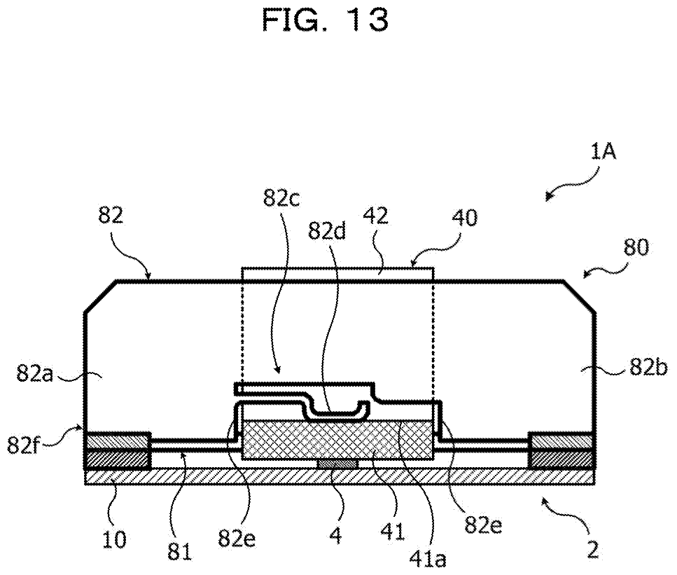

Furthermore, the electronic device adopting the configuration described below (FIGS. 13 to 18) may be obtained.

FIG. 13 is a view illustrating a first example of the electronic device according to the first embodiment. FIG. 13 is a schematic cross-sectional view of a main part of an example of the electronic device. Here, FIG. 13 is a schematic cross-sectional view of the electronic device when the heat sink fixing member is cut in a direction along a plane of one blade.

In the electronic device 1 described above, one row of the group of heat sinks 40 arranged above the board 10 is fixed by one blade 82 of the heat sink fixing member 80.

Whereas, in an electronic device 1A illustrated in FIG. 13, one heat sink 40 above the board 10 is fixed by one blade 82 of the heat sink fixing member 80. As in the electronic device 1A illustrated in FIG. 13, the heat sink fixing member 80 may fix and hold one heat sink 40 that is provided to the board 10 of the board unit 2 via the component unit 4 (including, for example, the electronic component 20, the heat spreader 30, and the TIM 70 as illustrated in FIG. 4).

In this case, the heat sink fixing member 80 includes: a frame 81 having a shape to surround one heat sink 40 and the component unit 4 provided under the heat sink 40; and a blade 82 whose both end parts 82a and 82b are connected to such a frame 81. The frame 81 is fixed to the board 10 by screwing or the like. At this time, a side surface of the heat sink 40 is guided by a guide part 82e provided at a portion 82c of the blade 82. The portion 82c of the blade 82 is inserted into a gap between adjacent fins 42 of the heat sink 40, and a pressing part 82d provided at the portion 82c abuts on the upper surface 41a of the base plate 41. The base plate 41 is pressed toward the component unit 4 and the board 10 mounted with the component unit 4, by the spring property of the pressing part 82d. This allows the heat sink 40 to be stably fixed, and stably maintains the fixed state.

The heat sink fixing member 80 as illustrated in FIG. 13 realizes the electronic device 1A in which the heat sink 40 above the board 10 is stably fixed and held.

In the electronic device LA, for example, by providing the frame 81 of the heat sink fixing member 80 along an outer peripheral portion on the board 10, or by adjusting a screwing position, it is possible to suppress deterioration of the degree of freedom in wiring arrangement and the electronic component mounting density of the board 10.

In the electronic device 1A, since the heat sink 40 is pressed and fixed by the plate-shaped blade 82 of the heat sink fixing member 80, a higher increasing effect of heat radiation area and a higher straightening effect may be obtained as compared an electronic device in which the heat sink 40 is pressed with a linear member (FIG. 1B) such as a wire or a rod-shaped member.

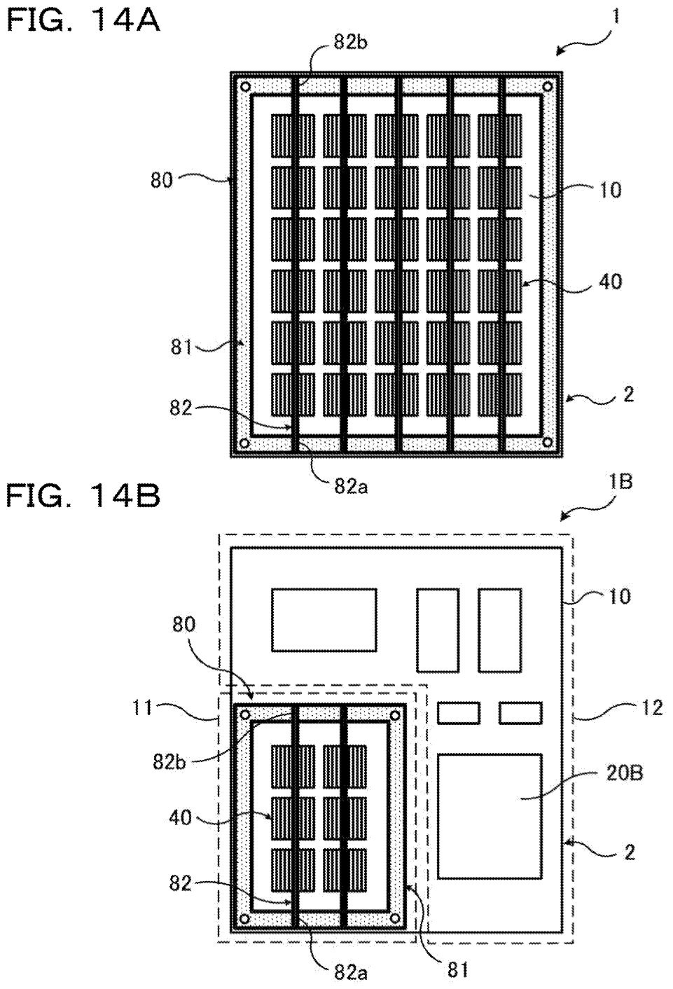

Furthermore, FIGS. 14A and 14B are views illustrating a second example of the electronic device according to the first embodiment. FIGS. 14A and 14B each are schematic plan views of a main part of an example of the electronic device.

In the electronic device 1 described above, as illustrated in FIG. 14A, there is used a heat sink fixing member 80 having a frame 81 having a shape surrounding a group of heat sinks 40 arranged above the board 10 (and the component units 4 individually provided under the group of heat sinks 40) and provided along an outer peripheral portion on the board 10. Corresponding to the group of heat sinks 40 in each row, there is provided a group of blades 82 each having both end parts 82a and 82b connected to the frame 81, and the group of blades 82 presses and fixes the group of heat sinks 40.

Whereas, in the electronic device 18 illustrated in FIG. 14B, there is used a heat sink fixing member 80 having a frame 81 having a shape surrounding a group of heat sinks 40 arranged in a partial region 11 on the board 10 (and the component units 4 individually provided under the group of heat sinks 40) and provided along an outer peripheral portion on the partial region 11. In the electronic device 1B, various electronic components 208 are mounted in another region 12 on the board 10. In the partial region 11 on the board 10, in correspondence to the group of heat sinks 40 in each row, there is provided a group of blades 82 each having both end parts 82a and 82b connected to the frame 81, and the group of blades 82 presses and fixes the group of heat sinks 40.

As described above, the heat sink fixing member 80 may be provided in the partial region 11 on the board 10.

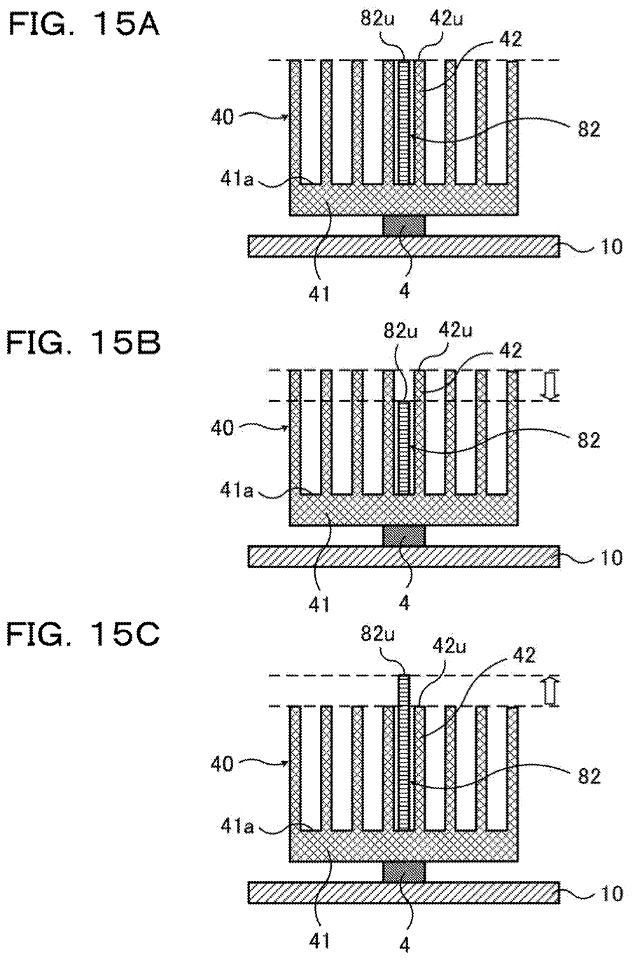

Furthermore, FIGS. 15A to 15C are views illustrating a third example of the electronic device according to the first embodiment. FIGS. 15A to 15C each are schematic cross-sectional views of a main part of an example of the electronic device. Here, FIGS. 15A to 15C each are schematic cross-sectional views of the electronic device when the heat sink fixing member is cut in a direction orthogonal to a direction along a plane of one blade.

In the electronic device 1 and the like, the blade 82 of the heat sink fixing member 80 can have a shape as illustrated in FIGS. 15A to 15C.

For example, as illustrated in FIG. 15A, the blade 82 has a shape in which a position of an upper end 82u when inserted into a gap between adjacent fins 42 of the heat sink 40 and abutting on the upper surface 41a of the base plate 41 is at the same height as an upper end 42u of the group of fins 42. Alternatively, as illustrated in FIG. 15B, the blade 82 has a shape in which a position of the upper end 82u when inserted into a gap between adjacent fins 42 of the heat sink 40 and abutting on the upper surface 41a of the base plate 41 is lower than the upper end 42u of the group of fins 42.

As illustrated in FIGS. 15A and 15B, in the blade 82 of the heat sink fixing member 80, a height from the upper surface 41a of the base plate 41 to be abutted can be adjusted within a range of the height of the group of fins 42 from the upper surface 41a of the base plate 41. In this case, increasing the height of the blade 82 within a range of the height of the group of fins 42 enhances rigidity (longitudinal rigidity) of the blade 82, and enhances a mechanical strength of the blade 82 and the heat sink fixing member 80 including the blade 82. Moreover, when the blade 82 is used as a part of a heat radiation member, increasing the height of the blades 82 within a range of the height of the group of fins 42 increases the heat radiation area, and enhances the heat radiation efficiency. In addition, when the blade 82 is used as a straightening plate, increasing the height of the blades 82 within a range of the height of the group of fins 42 enhances a straightening function, suppresses stagnation of heated refrigerant, and enhances the radiation efficiency.

As illustrated in FIG. 15C, the blade 82 may have a shape in which a position of the upper end 82u when inserted into a gap between adjacent fins 42 of the heat sink 40 and abutting on the upper surface 41a of the base plate 41 is higher than the upper end 42u of the group of fins 42. This may achieve, similarly to the above, improvement of a mechanical strength by enhancement of the rigidity, improvement of the heat radiation efficiency by increase of the heat radiation area, and improvement of the heat radiation efficiency by enhancement of the straightening function. However, since configuring the blade 82 to protrude from the group of fins 42 in this manner increases the height of the electronic device 1 and the like adopting this configuration to be tall, it is desirable that the height of the blade 82 is adjusted in consideration of restrictions on an installation location (a rack, a slot, inside the housing, and the like).

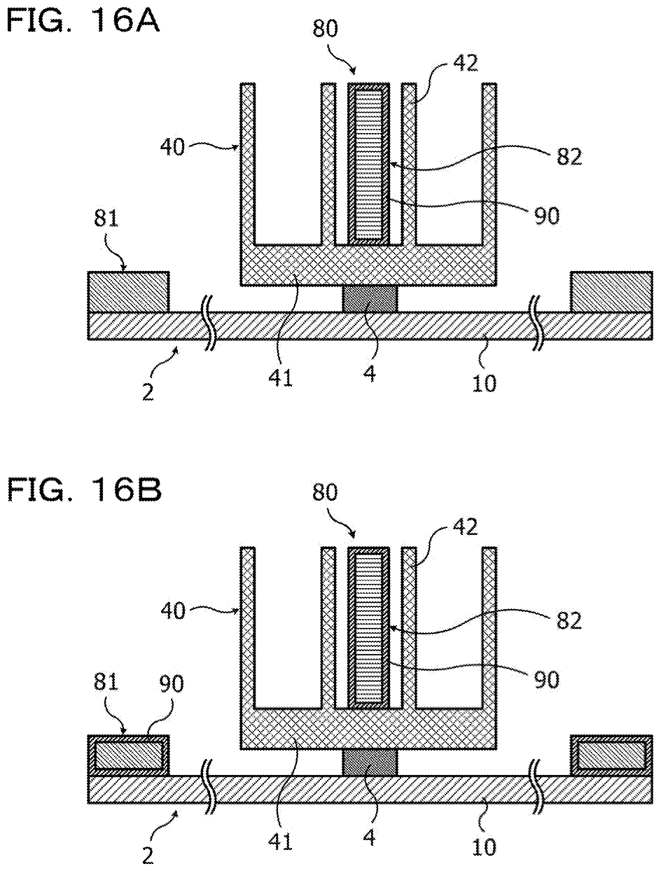

Furthermore, FIGS. 16A and 16B are views illustrating a fourth example of the electronic device according to the first embodiment. FIGS. 16A and 16B each are schematic cross-sectional views of a main part of an example of the electronic device. Here, FIGS. 16A and 168 each are schematic cross-sectional views of the electronic device when the heat sink fixing member is cut in a direction orthogonal to a direction along a plane of one blade.

In the electronic device 1 and the like, various conductive and insulating materials can be used for each of the frame 81 and the blade 82 of the heat sink fixing member 80. Examples of the conductive material include stainless steel, aluminum, copper, and the like. Examples of the insulating material include a resin material, a ceramic material, a glass material, and the like.

Here, when a conductive material is used for the blade 82, the following may occur. In other words, for example, when the heat sink fixing member 80 is attached to the board unit 2, and one blade 82 using a conductive material abuts on one row of the group of heat sinks 40, the group of heat sinks 40 in the row will be electrically connected via the blade 82. Whereas, in the electronic device 1, functionally, the electronic component 20 of the component unit 4 (including the electronic component 20, the heat spreader 30, and the TIM 70 as illustrated in FIG. 4, for example) may be electrically connected to the heat sink 40 provided on the electronic component 20. In such a case, as described above, when the group of heat sinks 40 in the row is electrically connected via the blade 82, the group of electronic components 20 of the component units 4 in the row is electrically connected via the group of heat sinks 40, a predetermined function may not be realized in the electronic device 1.

Thus, for example, as illustrated in FIG. 16A, a surface of the blade 82 using a conductive material is coated with an insulating layer 90 using an insulating material. This may avoid electrical connection of the group of heat sinks 40 in the row via the blade 82, even if the heat sink fixing member 80 is attached to the board unit 2 and one blade 82 abuts on one row of the group of heat sinks 40. By using a conductive material for a part of the blade 82, in other words, for example, a part inside the insulating layer 90, higher thermal conductivity is obtained than that of a case where the entire blade 82 is made of an insulating material, and the blade 82 may function as a part of a heat radiation member. When reducing a thickness of the insulating layer 90 within a range capable of avoiding electrical connection with the heat sink 40, or using an insulating material having a relatively high thermal conductivity such as aluminum nitride for the insulating layer 90, it Is possible to suppress deterioration of the thermal conductivity of the blade 82.

Furthermore, as illustrated in FIG. 168, in the heat sink fixing member 80, a surface of the frame 81 connected with the blade 82 may be coated with the insulating layer 90 using the insulating material as described above, in addition to the surface of the blade 82. This suppresses electrical connection of the group of heat sinks 40 in a same row via one blade 82, and also suppresses electrical connection of the group of heat sinks 40 in different rows via different blades 82.

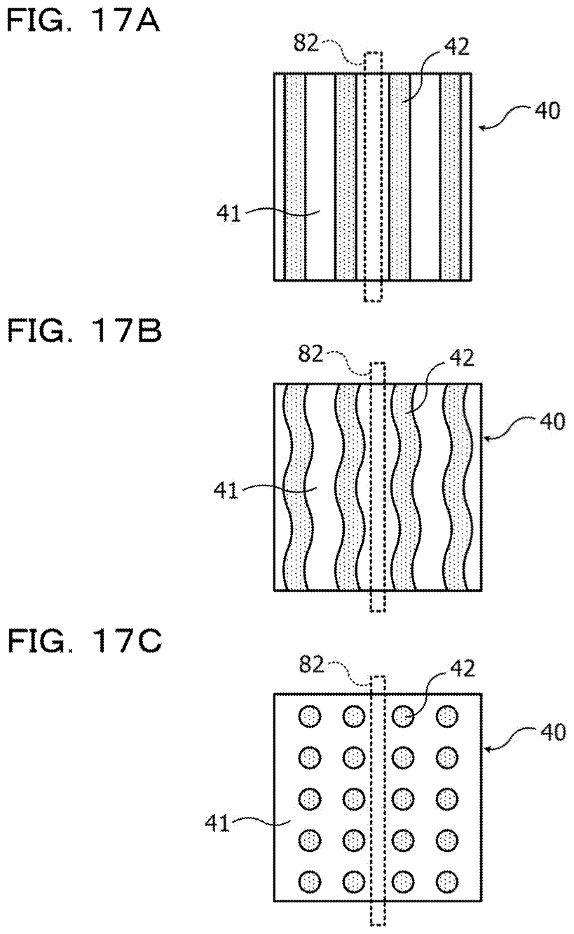

Furthermore, FIGS. 17A to 17C are views illustrating a fifth example of the electronic device according to the first embodiment. FIGS. 17A to 17C each are schematic plan views of a main part of an example of the heat sink used in the electronic device.

As the heat sink 40 used in the electronic device 1 and the like, for example, a heat sink having a group of flat fins 42 erecting in parallel on the base plate 41 as illustrated in FIG. 17A is used. In addition, as the heat sink 40, for example, a heat sink having a group of fins 42 in a corrugated shape erecting on the base plate 41 as illustrated in FIG. 17B may be used. As the heat sink 40, for example, a heat sink having a group of pin-shaped fins 42 standing on the base plate 41 as illustrated in FIG. 17C may be used. In a gap between adjacent fins 42 among a group of fins 42 having a flat shape, a corrugated shape, and a pin shape as illustrated in FIGS. 17A to 17C, the blade 82 of the heat sink fixing member 80 (individually illustrated by dotted lines in FIGS. 17A to 17C) is inserted, to fix heat sink 40.

Thus, the fins 42 of various shapes may be used for the heat sink 40 of the electronic device 1 and the like.

Furthermore, FIG. 18 is a view illustrating a sixth example of the electronic device according to the first embodiment. FIG. 18 is a schematic plan view of a main part of an example of the electronic device.

An electronic device 1C illustrated in FIG. 18 has a configuration in which a heat sink fixing member 80 includes a bent blade 82C. Both end parts 82a and 82b of the blade 82C are respectively connected to orthogonal portions 81a and 81c and orthogonal portions 81b and 81d of a frame 81. The heat sink fixing member 80 having such a blade 82C is attached to the board unit 2 such that the blade 82C is inserted into a gap between adjacent fins 42 of each of the group of heat sinks 40 that is arranged above the board 10 so that a plane direction of a group of fins 42 is orthogonal to the board 10. In a region of the board 10 where the group of heat sinks 40 are not arranged, various electronic components 20B may be mounted.

As in the electronic device 1C, the shape and arrangement of the blade 82C of the heat sink fixing member 80 may be adjusted on the basis of the arrangement of the group of heat sinks 40 mounted above the board 10 (position, orientation of the fins 42 in the plane direction).

Furthermore, in the description above, as the frame 81 of the heat sink fixing member 80, as an example, there has been described the rectangular frame 81 surrounding the group of heat sinks 40 (and the group of component units 4) arranged above the board 10. However, the shape of the frame 81 is not limited to the example described above. For example, when a certain strength of the heat sink fixing member 80 can be secured, a portion in the frame 81 described above other than the connection portions of both end parts 82a and 82b of the blade 82 may be removed.

### Second Embodiment

Here, description will be given to, as a second embodiment, an example of an immersion cooling system that performs cooling by immersing, in a cooling liquid, the electronic device 1 and the like described in the first embodiment described above.

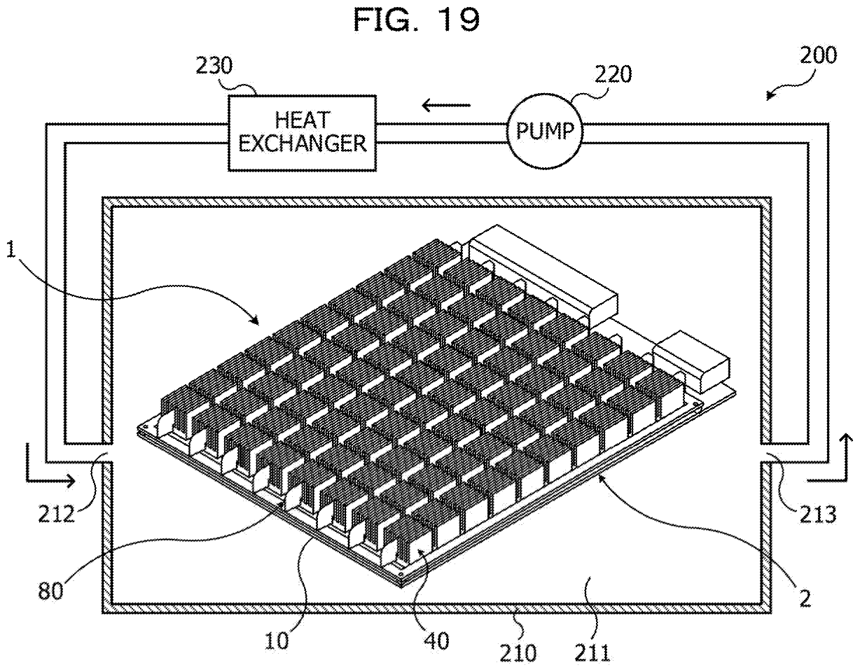

FIG. 19 is a view illustrating an example of the immersion cooling system according to the second embodiment.

An immersion cooling system 200 illustrated in FIG. 19 includes: an immersion tank 210 that stores a cooling liquid 211 such as a fluorine-based inert liquid; a pump 220 connected to a discharge port 213 of the immersion tank 210 by a pipe; and a heat exchanger 230 connected by the pipe to the pump 220 and a supply port 212 of the immersion tank 210. The pump 220 allows the cooling liquid 211 in the immersion tank 210 to be discharged from the discharge port 213 and sent to the heat exchanger 230, and allows the cooling liquid 211 cooled by the heat exchanger 230 to be sent into the immersion tank 210 from the supply port 212. In the immersion cooling system 200, the cooling liquid 211 is thus circulated.

For example, the electronic device 1 described in the first embodiment described above is Immersed in the immersion tank 210 that stores the cooling liquid 211 of such an immersion cooling system 200. Although not illustrated here, the electronic device 1 includes, as described above, a group of component units 4 (each including, for example, an electronic component 20, a heat spreader 30, and a TIM 70 as illustrated in FIG. 4) including the electronic component 20 that generates heat accompanying operation. Heat of the group of component units 4 of the electronic device 1 immersed in the cooling liquid 211 in the immersion tank 210 is transmitted to the group of heat sinks 40, and the heat transmitted to the group of heat sinks 40 is transmitted to the cooling liquid 211. This cools the group of heat sinks 40 and the group of component units 4, and suppresses overheating of the electronic component 20 included in each of the group of component units 4 and suppresses damage and performance deterioration due to the overheating.

In the electronic device 1, the group of heat sinks 40 above a board 10 is collectively fixed by a heat sink fixing member 80. In the electronic device 1, the heat sink fixing member 80 may fix the group of heat sinks 40 stably against a flow of the cooling liquid 211 generated in the immersion tank 210, and stably maintain the fixed state. Therefore, in the immersion cooling system 200, for example, it is possible to increase a flow rate of the cooling liquid 211 and increase cooling efficiency.

Furthermore, in the electronic device 1, since the group of heat sinks 40 above the board 10 is collectively fixed by the heat sink fixing member 80, deterioration of a degree of freedom in wiring arrangement and an electronic component mounting density of the board 10 may be suppressed.

Moreover, in the electronic device 1, the TIM 70 that is excellent in thermal conductivity even with a low adhesive strength may be used between with the heat sink 40 for each of the component units 4. Therefore, it is possible to enhance thermal conduction efficiency from each electronic component 20 to each heat sink 40, efficiently transmit the heat from each heat sink 40 to the cooling liquid 211, and enhance cooling efficiency of each electronic component 20.

Here, the electronic device 1 has been described as an example, but immersion cooling may be similarly performed by immersing other electronic devices 1A, 1B, and 1C described in the first embodiment described above, in the cooling liquid 211 in the immersion tank 210 of the immersion cooling system 200.

### Third Embodiment

The electronic device 1 and the like as described in the first embodiment described above can be mounted to various kinds of electronic equipment. For example, the electronic device 1 and the like can be mounted to various kinds of electronic equipment such as a computer (a personal computer, a supercomputer, a server, or the like), a smartphone, a portable telephone, a tablet terminal, a sensor, a camera, an audio apparatus, a measuring device, an inspection device, and a manufacturing device. Here, an example of electronic equipment using the electronic device 1 and the like will be described as a third embodiment.

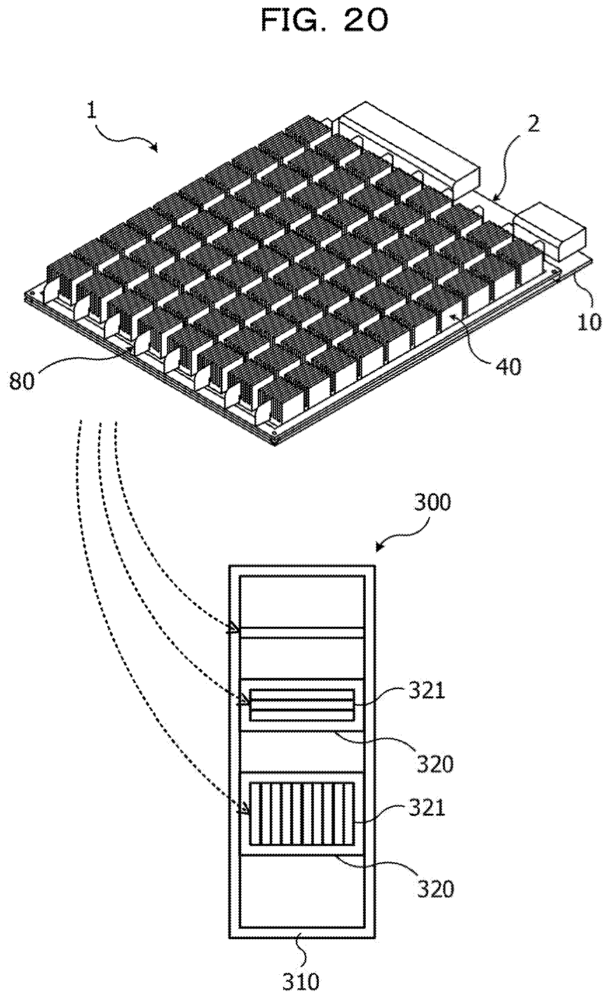

FIG. 20 is a view illustrating an example of the electronic equipment according to the third embodiment.

As illustrated in FIG. 20, for example, an electronic device 1 (an upper figure in FIG. 20) in which a heat sink fixing member 80 is attached to a board unit 2 as described in the first embodiment described above is directly mounted to a rack 310 of electronic equipment 300 (a lower figure in FIG. 20) Including the rack 310. Alternatively, the electronic device 1 is mounted in a slot 321 of a housing 320 mounted to the rack 310 of the electronic equipment 300, in a flat or vertical position. Thus, the electronic equipment 300 mounted with the electronic device 1 is realized.

Note that the electronic equipment 300 mounted with the electronic device 1 in this way may be immersed in a cooling liquid 211 in an immersion tank 210 of an immersion cooling system 200 as described in the second embodiment described above. This allows immersion cooling of the electronic equipment 300 and the electronic device 1 mounted to the electronic equipment 300 to be performed.

Here, the electronic device 1 has been described as an example, but other electronic devices 1A, 1B, and 1C described in the first embodiment described above can be similarly mounted to the rack 310 or the slot 321 of the electronic equipment 300. The immersion cooling may be performed by immersing the rack 310 and the slot 321 of the electronic equipment 300 mounted with the electronic devices 1A, 1B, and 1C, in the cooling liquid 211 in the immersion tank 210 of the immersion cooling system 200. Without limiting to such electronic equipment 300 including the rack 310, the electronic device 1 and the like can be mounted to various kinds of electronic equipment (in a housing thereof, another board in the housing, or the like).

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A heat sink fixing member comprising:
a frame that is provided above a board of a unit and surrounds a first electronic component and a first heat sink; and
a blade in which both end parts are connected to the frame, a portion between the both end parts is erected in a gap in a first fin group, and a side closer to the board in the portion abuts on a first base plate,
wherein the unit includes:
the board;
the first electronic component mounted on the board; and
the first heat sink that is provided on the first electronic component, and has the first base plate and the first fin group that protrudes from the first base plate.

2. The heat sink fixing member according to claim 1,
wherein the blade has, at a side closer to the board in the portion, a first pressing part that abuts on the first base plate and presses the first base plate toward the first electronic component and the board.

3. The heat sink fixing member according to claim 1,
wherein the blade has, at a side closer to the board in the portion, a first guide part opposed to a side surface of the first base plate and configured to guide a side surface of the first base plate.

4. The heat sink fixing member according to claim 1, wherein
each of the first fin group is plate-shaped and is erected on the first base plate in parallel with each other, and
the portion of the blade is plate-shaped, and is erected in parallel with the first fin group in a gap of the first fin group.

5. The heat sink fixing member according to claim 1, wherein the unit further includes:
a second electronic component mounted on the board at a position different from the first electronic component; and
a second heat sink that is provided on the second electronic component, and has a second base plate and a second fin group that protrudes from the second base plate,
wherein the frame is provided on the board, and surrounds the first electronic component and the first heat sink, and the second electronic component and the second heat sink, and
in the blade, the portion between the both end parts is erected in a gap of the first fin group and a gap of the second fin group, and a side closer to the board in the portion abuts on the first base plate and the second base plate.

6. The heat sink fixing member according to claim 5,
wherein the blade has, at a side closer to the board in the portion, a second pressing part that abuts on the second base plate and presses the second base plate toward the second electronic component and the board.

7. The heat sink fixing member according to claim 5,
wherein the blade has, at a side closer to the board in the portion, a second guide part opposed to a side surface of the second base plate and configured to guide a side surface of the second base plate.

8. The heat sink fixing member according to claim 5,
wherein a height from the board to an upper end of the first base plate is different from a height from the board to an upper end of the second base plate.

9. An electronic device comprising:
a board;
a first electronic component mounted on the board;
a first heat sink that is provided on the first electronic component, and has a first base plate and a first fin group that protrudes from the first base plate; and
a heat sink fixing member provided on the board,
wherein the heat sink fixing member includes:
a frame that is provided on the board and surrounds the first electronic component and the first heat sink; and
a blade in which both end parts are connected to the frame, a portion between the both end parts is erected in a gap in the first fin group, and a side closer to the board in the portion abuts on the first base plate.
